(19) United States
(12) Patent Application Publication
(10) Pub. No.: US 2025/0234524 A1
(43) Pub. Date: Jul. 17, 2025

(54) MEMORY DEVICE INCLUDING WORD LINE STRUCTURE WITH HIGH-K GATE DIELECTRIC LAYER AND METHOD FOR PREPARING THE SAME

(71) Applicant: NANYA TECHNOLOGY CORPORATION, NEW TAIPEI CITY (TW)

(72) Inventor: YING-CHENG CHUANG, TAOYUAN CITY (TW)

(21) Appl. No.: 19/019,559

(22) Filed: Jan. 14, 2025

Related U.S. Application Data
(63) Continuation-in-part of application No. 18/414,599, filed on Jan. 17, 2024.

(51) Int. Cl. H10B 12/00

(52) U.S. Cl. CPC H10B 12/482; H10B 12/315; H10B 12/485; H10B 12/488

(57) ABSTRACT

The present application discloses a memory device and a method for fabricating the same. The memory device includes a semiconductor substrate having an active area, and a word line structure extending across the active area. The word line structure includes a metal gate electrode layer and a high-k gate dielectric layer surrounding the metal gate electrode layer. The memory device also includes a first source/drain region and a second source/drain region disposed in the active area and at opposite sides of the word line structure. The memory device further includes a bit line structure disposed over and electrically connected to the first source/drain region, and a capacitor disposed over and electrically connected to the second source/drain region.

### CROSS-REFERENCE TO RELATED APPLICATION

This application is a continuation-in-part application of U.S. Non-Provisional application Ser. No. 18/414,599 filed Jan. 17, 2024, which is incorporated herein by reference in its entirety.

### TECHNICAL FIELD

The present disclosure relates to a memory device and a method for preparing the same, and more particularly, to a memory device including a word line structure with a high-k gate dielectric layer and a method for preparing the same.

### DISCUSSION OF THE BACKGROUND

Due to their structural simplicity, dynamic random-access memories (DRAMs) can provide more memory cells per unit chip area than other types of memories, such as static random-access memories (SRAMs). A DRAM consists of a plurality of DRAM cells, each of which includes a capacitor for storing information and a transistor coupled to the capacitor to regulate charge and discharge of the capacitor. During a read operation, a word line (WL) is asserted, turning on the transistor. The enabled transistor allows a voltage across the capacitor to be read by a sense amplifier through a bit line (BL). During a write operation, data to be written is provided on the BL while the WL is asserted.

To meet growing demands for memory storage, dimensions of DRAM memory cells are continuously decreasing, resulting in significantly increased packing densities. However, manufacturing and integration of memory devices involve many complex steps and operations, making integration processes increasingly challenging. As the complexity of manufacturing and integrating memory devices increases, deficiencies may arise. Consequently, ongoing improvements in structure and manufacturing processes of memory devices are essential to overcome challenges and enhance performance.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a memory device including a semiconductor substrate having an active area; a word line structure extending across the active area; a first source/drain region and a second source/drain region disposed in the active area and at opposite sides of the word line structure; a bit line structure disposed over and electrically connected to the first source/drain region; and a capacitor disposed over and electrically connected to the second source/drain region. The word line structure comprises a metal gate electrode layer and a high-k gate dielectric layer surrounding the metal gate electrode layer. The first source/drain region and the second source/drain region are formed of silicon phosphide, phosphorus-doped silicon carbon, silicon carbide, silicon germanium, silicon-germanium-tin alloy, or silicon-germanium-boron alloy.

Another aspect of the present disclosure provides a memory device including a semiconductor substrate having an active area; a word line structure extending across the active area, wherein the word line structure comprises a metal gate electrode layer and a high-k gate dielectric layer surrounding the metal gate electrode layer; a first source/drain region and a second source/drain region disposed in the active area and at opposite sides of the word line structure; a dielectric layer disposed over the semiconductor substrate and covering the word line structure; a bit line structure disposed over the dielectric layer and electrically connected to the first source/drain region; a capacitor disposed over the dielectric layer and electrically connected to the second source/drain region; a mask layer disposed between the second source/drain region and the capacitor; and a polysilicon stack disposed in the mask layer. The polysilicon stack comprises a first polysilicon layer and a second polysilicon layer disposed over the first polysilicon layer, wherein the first polysilicon layer is undoped and the second polysilicon layer is doped. An interface between the dielectric layer and the high-k gate dielectric layer is substantially level with an interface between the dielectric layer and the metal gate electrode layer. The mask layer is in direct contact with the high-k gate dielectric layer.

Another aspect of the present disclosure provides a method for preparing a memory device. The method includes forming a doped region in a semiconductor substrate; performing a first etching process on the semiconductor substrate to form a trench, thereby forming a first source/drain region and a second source/drain region in the doped region and at opposite sides of the trench; forming a high-k dielectric material lining the trench, and filling the trench with a metal material; performing a second etching process on the high-k dielectric material and the metal material to form a recess, thereby forming a high-k gate dielectric layer of a word line structure and a metal gate electrode layer of the word line structure, wherein a width of the recess is greater than a width of the metal gate electrode layer; forming a bit line structure over and electrically connected to the first source/drain region; and forming a capacitor over and electrically connected to the second source/drain region.

Another aspect of the present disclosure provides a method for preparing a memory device. The method includes forming a doped region in a semiconductor substrate; depositing a mask material over the substrate; forming a patterned mask with an opening over the mask material; performing a first etching process on the substrate using the patterned mask as an etching mask to form a trench in the substrate, and forming a mask layer, a first source/drain region and a second source/drain region, wherein the first source/drain region and the second source/drain region are at opposite sides of the trench, and wherein the mask layer is over the first source/drain region and the second source/drain region; forming a high-k dielectric material lining the trench, and filling the trench with a metal material; performing a second etching process on the high-k dielectric material and the metal material to form a recess, thereby forming a high-k gate dielectric layer of a word line structure and a metal gate electrode layer of the word line structure, wherein a width of the recess is greater than a width of the metal gate electrode layer; depositing a dielectric layer covering the mask layer and the word line structures; forming a bit line structure over and electrically connected to the first source/drain region; and forming a capacitor over and electrically connected to the second source/drain region.

Embodiments of a memory device and a method for preparing the same are provided in the disclosure. In some embodiments, the memory device includes a word line structure disposed in a semiconductor substrate. The word line structure includes a metal gate electrode layer and a high-k gate dielectric layer surrounding the metal gate electrode layer. Consequently, gate-to-substrate leakage current can be reduced while suppressing channel leakage current and increasing a channel length. As a result, a performance of the memory device is enhanced.

The foregoing has outlined rather broadly the features and technical advantages of the present disclosure in order that the detailed description of the disclosure that follows may be better understood. Additional features and advantages of the disclosure are described below, and form the subject of the claims of the disclosure. It should be appreciated by those skilled in the art that the conception and specific embodiments disclosed may be readily utilized as a basis for modifying or designing other structures or processes for carrying out the purposes of the present disclosure. It should also be realized by those skilled in the art that such equivalent constructions do not depart from the spirit and scope of the disclosure as set forth in the appended claims.

### BRIEF DESCRIPTION OF THE DRA WINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

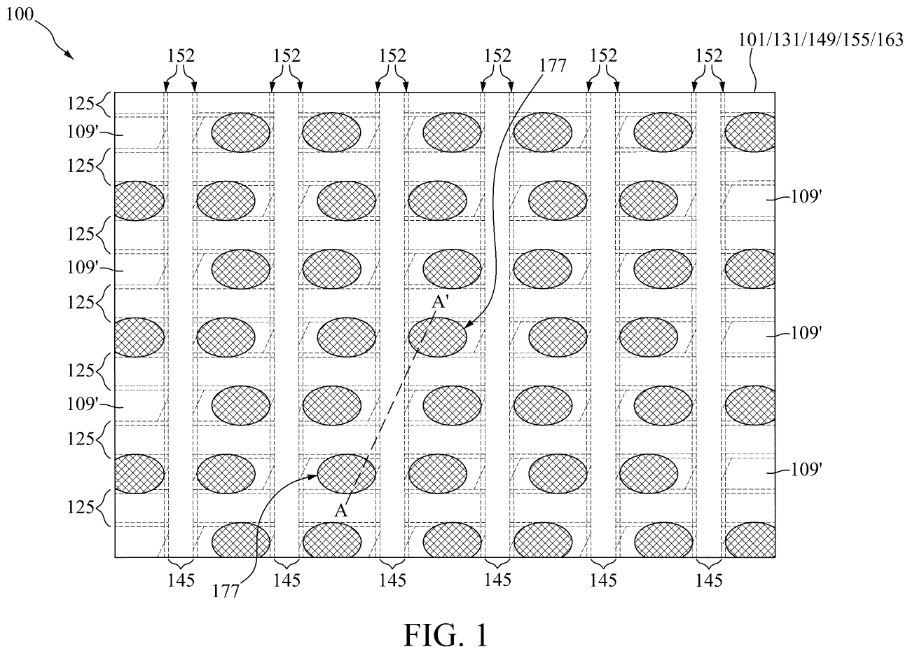

FIG. 1 is a top view of a memory device in accordance with some embodiments of the present disclosure.

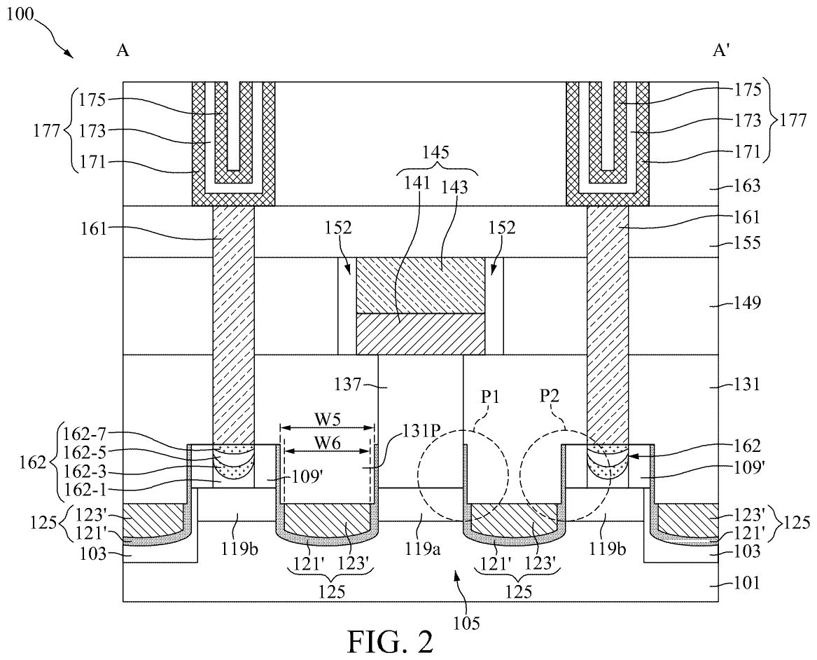

FIG. 2 is a cross-sectional view of a memory device along a line A-A′ in FIG. 1 in accordance with some embodiments of the present disclosure.

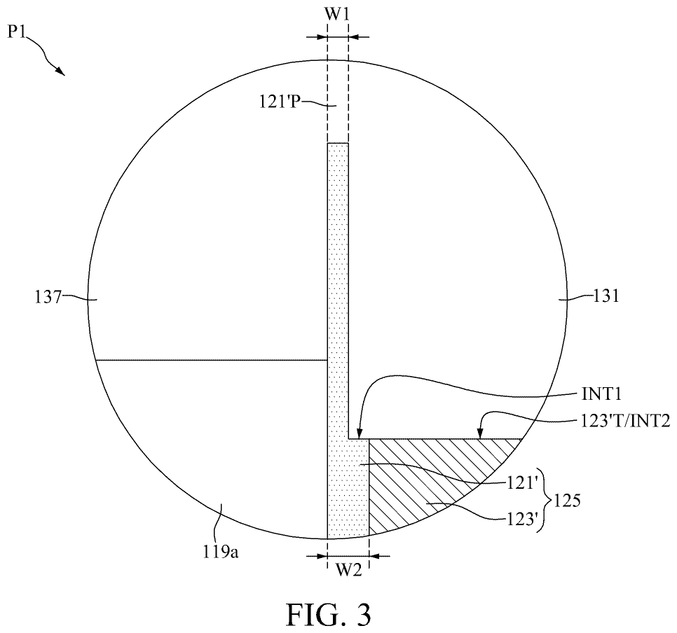

FIG. 3 is an enlarged view of a portion P1 of the memory device in FIG. 2 in accordance with some embodiments of the present disclosure.

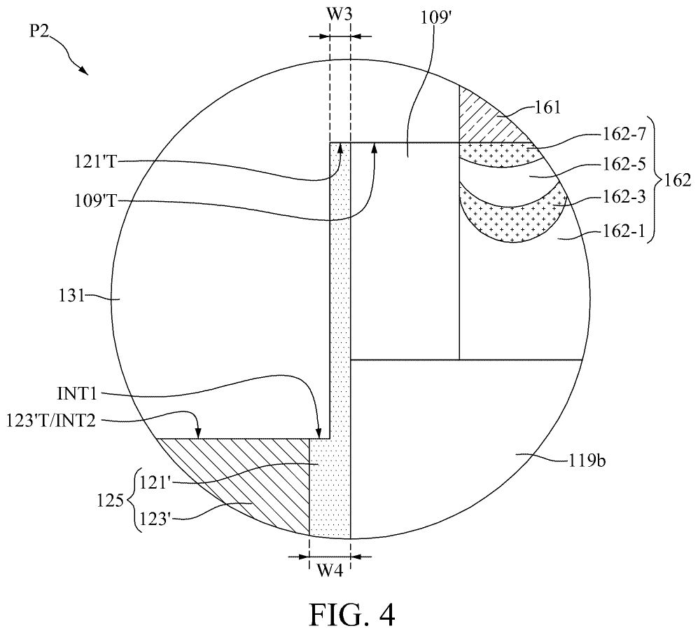

FIG. 4 is an enlarged view of another portion P2 of the memory device in FIG. 2 in accordance with some embodiments of the present disclosure.

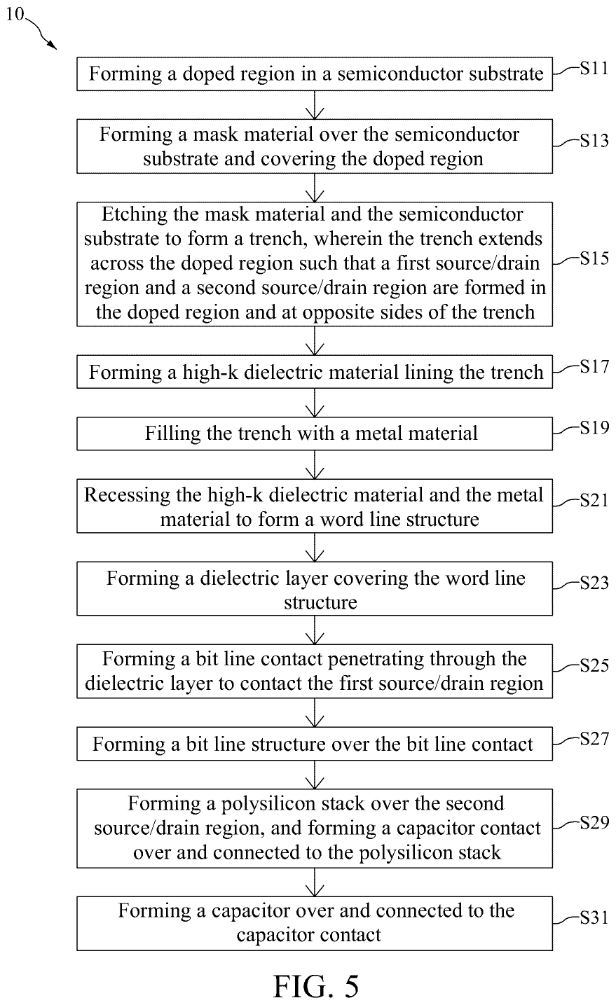

FIG. 5 is a flow diagram of a method for preparing a memory device in accordance with some embodiments of the present disclosure.

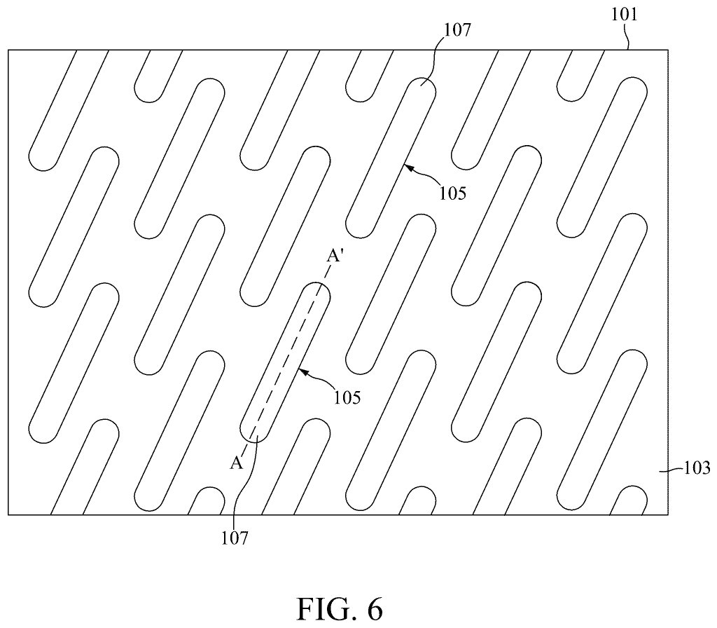

FIG. 6 is a top view of an intermediate stage of forming doped regions in a semiconductor substrate during formation of a memory device in accordance with some embodiments of the present disclosure.

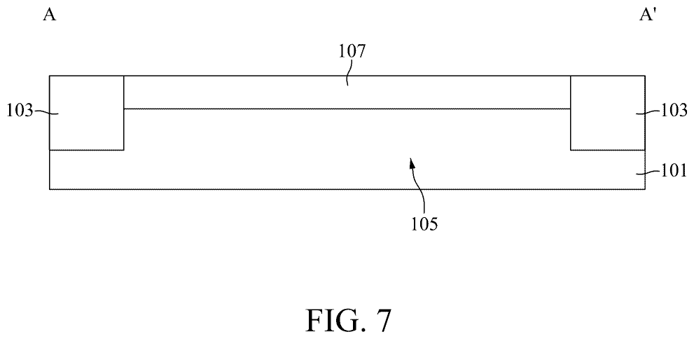

FIG. 7 is a cross-sectional view of an intermediate stage in the formation of the memory device along a line A-A′ in FIG. 6 in accordance with some embodiments of the present disclosure.

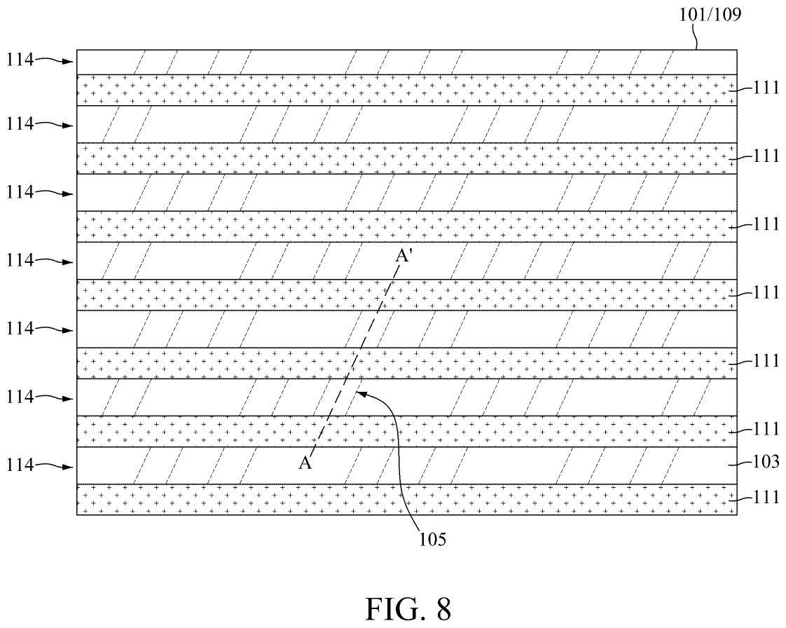

FIG. 8 is a top view of an intermediate stage of sequentially forming a mask material and a patterned mask over the semiconductor substrate during the formation of the memory device in accordance with some embodiments of the present disclosure.

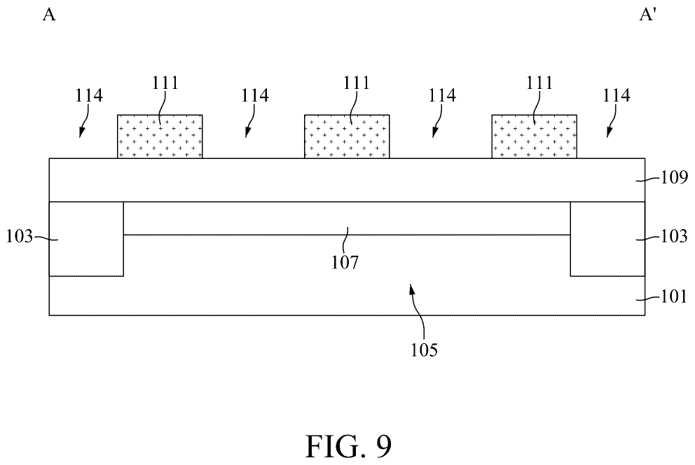

FIG. 9 is a cross-sectional view of an intermediate stage in the formation of the memory device along a line A-A′ in FIG. 8 in accordance with some embodiments of the present disclosure.

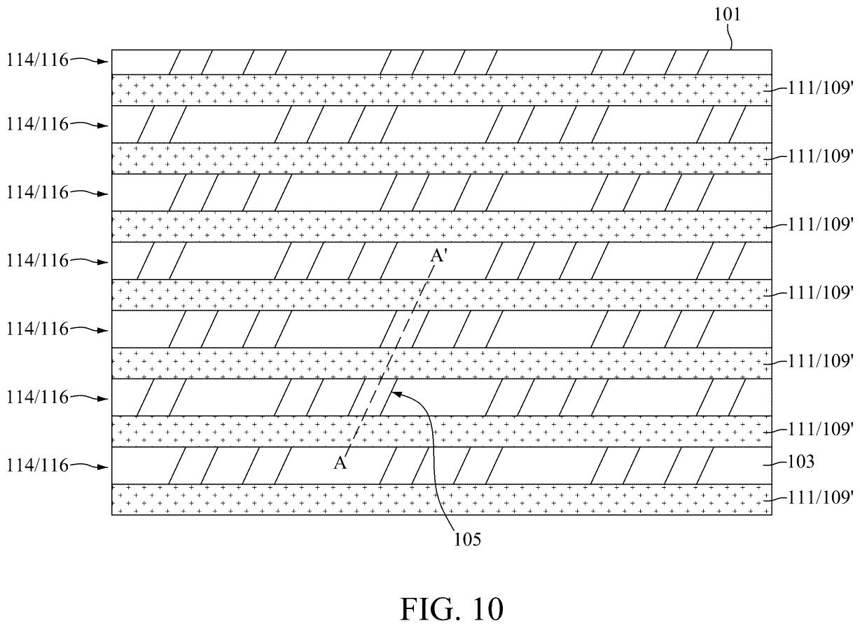

FIG. 10 is a top view of an intermediate stage of etching the mask material and the semiconductor substrate to form trenches across the doped regions and forming source/drain regions during the formation of the memory device in accordance with some embodiments of the present disclosure.

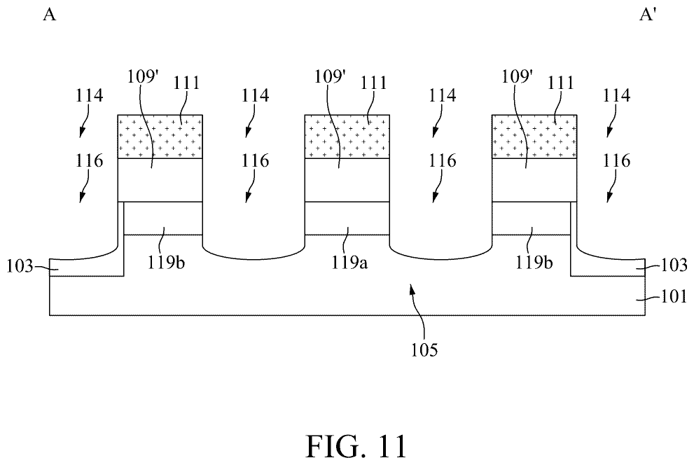

FIG. 11 is a cross-sectional view of an intermediate stage in the formation of the memory device along a line A-A′ in FIG. 10 in accordance with some embodiments of the present disclosure.

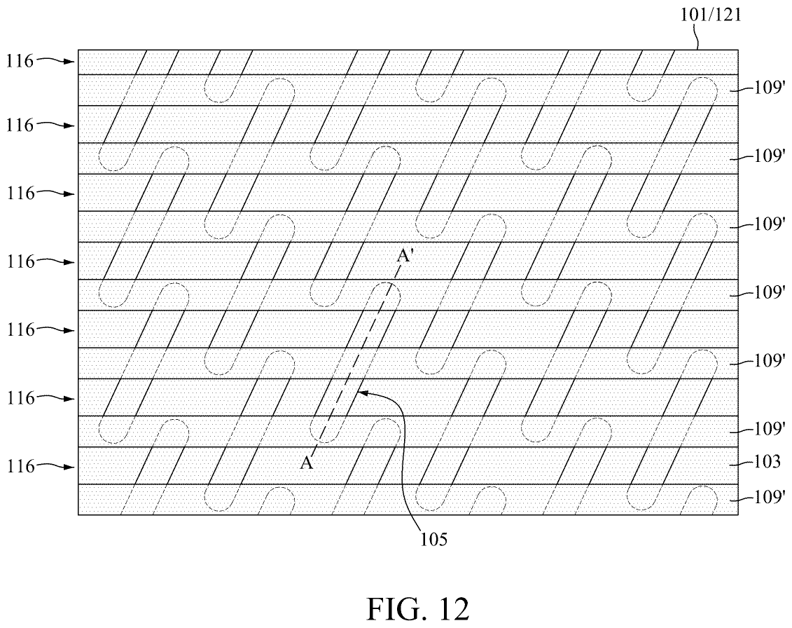

FIG. 12 is a top view of an intermediate stage of forming a high-k dielectric material lining the trenches during the formation of the memory device in accordance with some embodiments of the present disclosure.

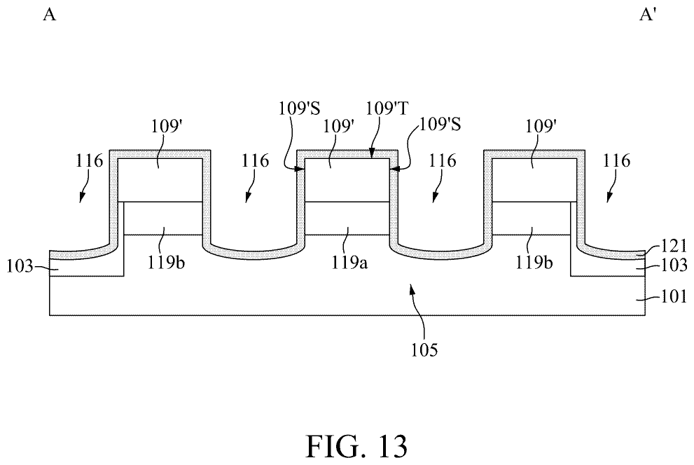

FIG. 13 is a cross-sectional view of an intermediate stage in the formation of the memory device along a line A-A′ in FIG. 12 in accordance with some embodiments of the present disclosure.

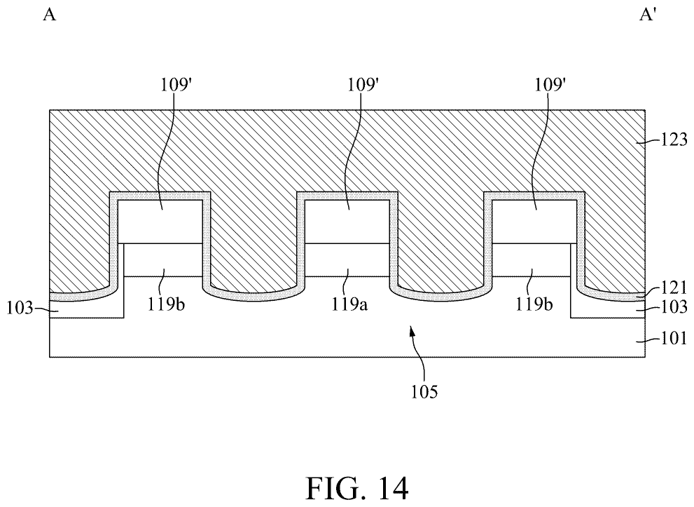

FIG. 14 is a cross-sectional view of an intermediate stage of filling the trenches with a metal material during the formation of the memory device in accordance with some embodiments of the present disclosure.

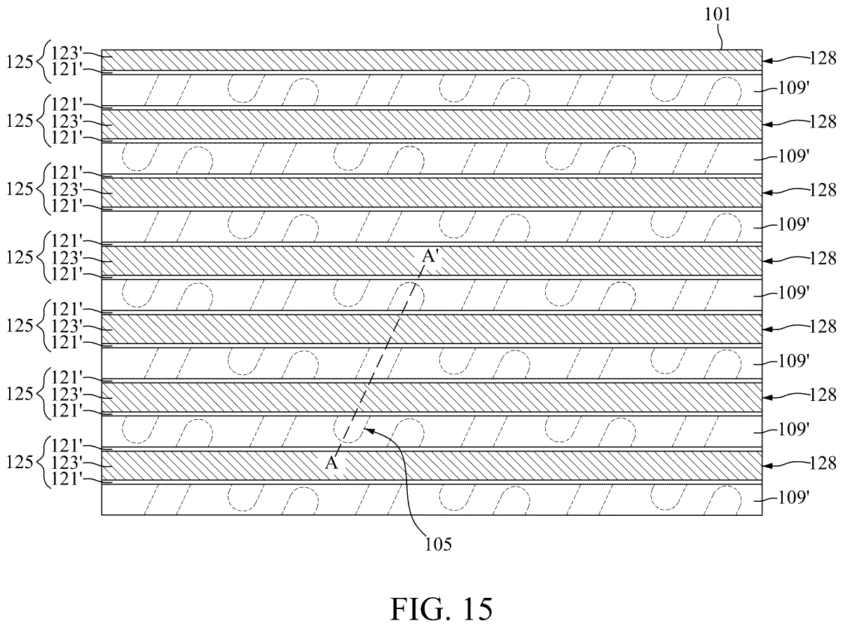

FIG. 15 is a top view of an intermediate stage of recessing the high-k dielectric material and the metal material to form word line structures during the formation of the memory device in accordance with some embodiments of the present disclosure.

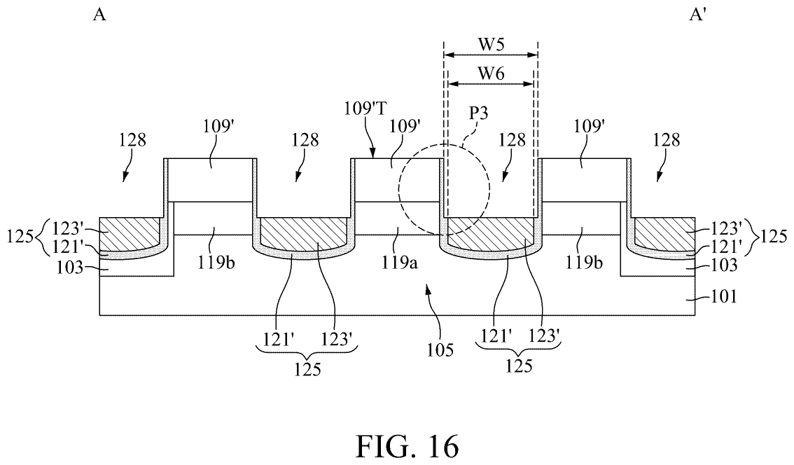

FIG. 16 is a cross-sectional view of an intermediate stage in the formation of the memory device along a line A-A′ in FIG. 15 in accordance with some embodiments of the present disclosure.

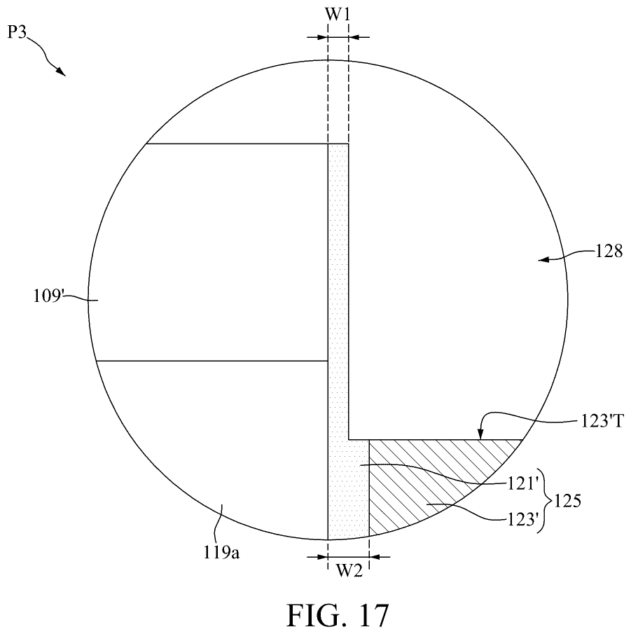

FIG. 17 is an enlarged view of a portion P3 of the memory device in FIG. 16 in accordance with some embodiments of the present disclosure.

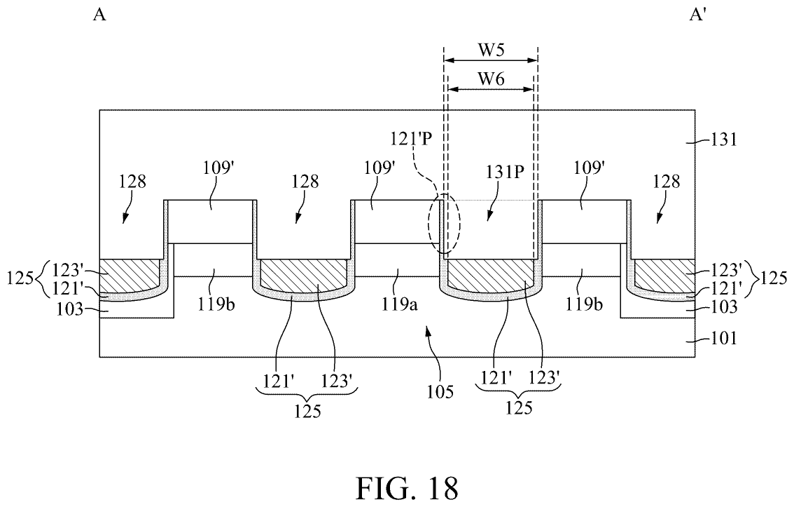

FIG. 18 is a cross-sectional view of an intermediate stage of forming a dielectric layer covering the word line structures during the formation of the memory device in accordance with some embodiments of the present disclosure.

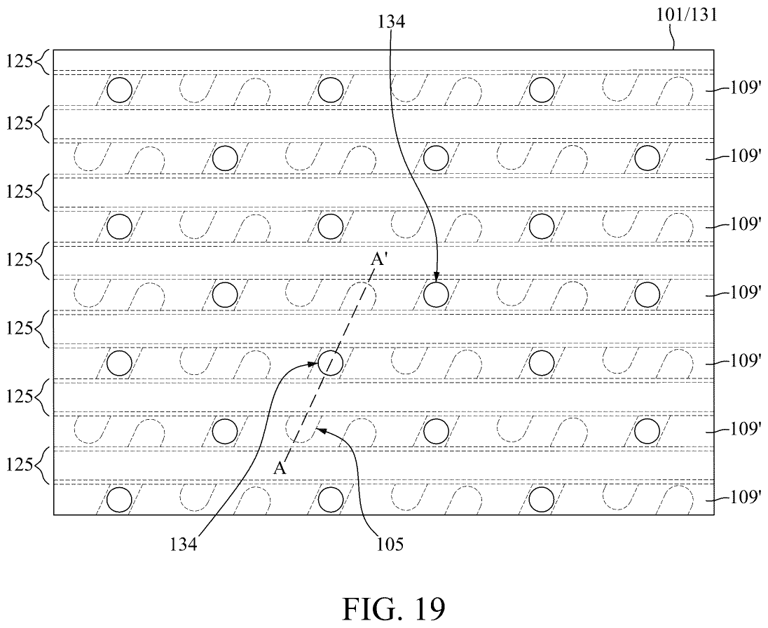

FIG. 19 is a top view of an intermediate stage of etching the dielectric layer to form bit line contact openings during the formation of the memory device in accordance with some embodiments of the present disclosure.

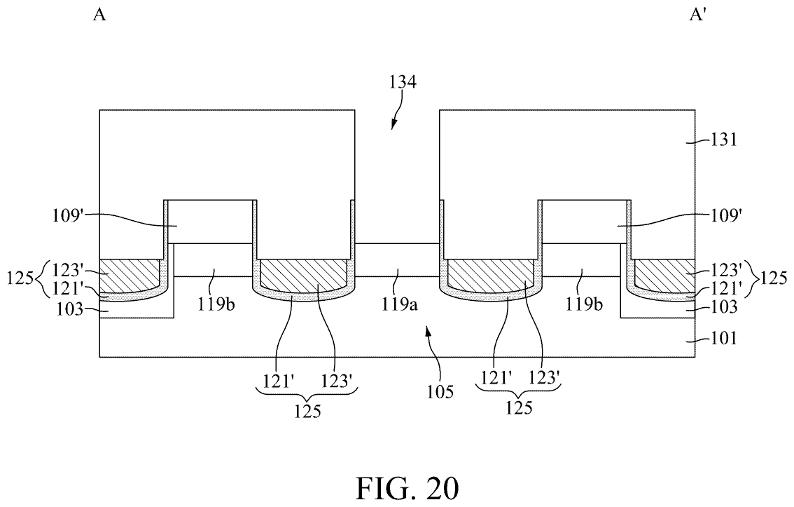

FIG. 20 is a cross-sectional view of an intermediate stage in the formation of the memory device along a line A-A′ in FIG. 19 in accordance with some embodiments of the present disclosure.

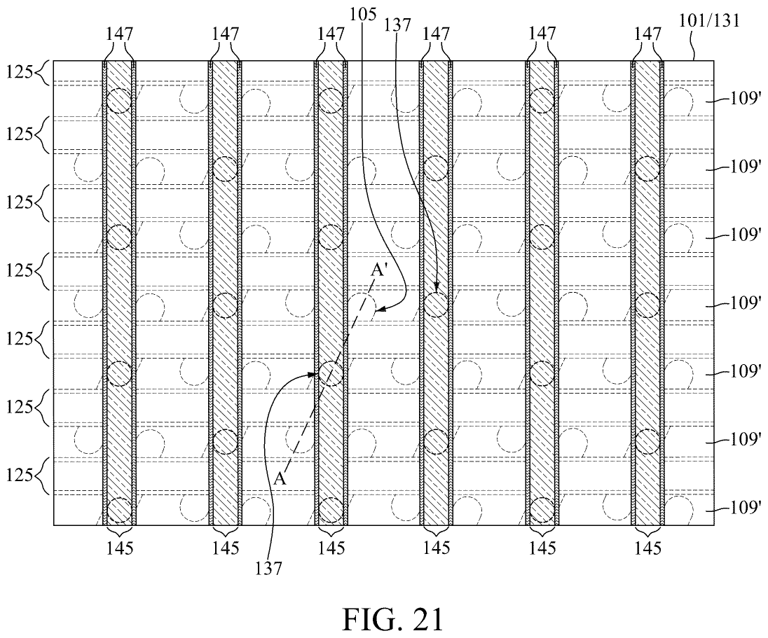

FIG. 21 is a top view of an intermediate stage of forming bit line contacts, bit line structures and dielectric spacers during the formation of the memory device in accordance with some embodiments of the present disclosure.

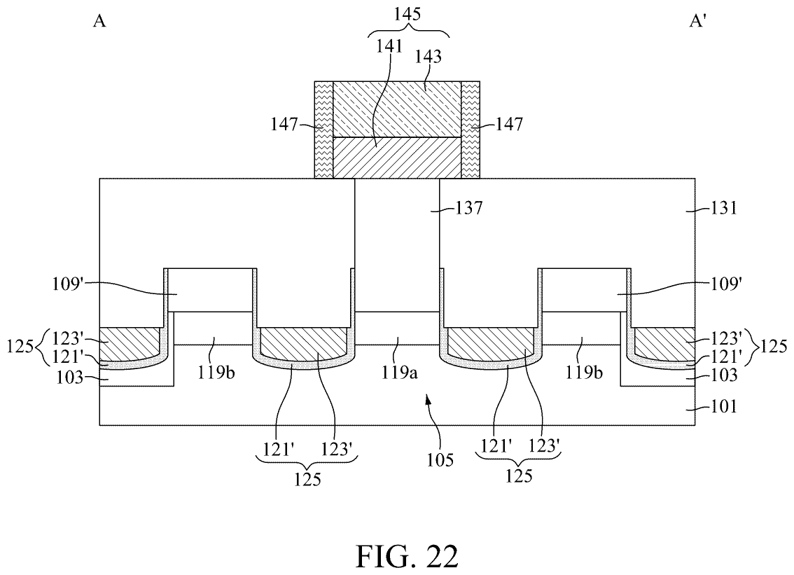

FIG. 22 is a cross-sectional view of an intermediate stage in the formation of the memory device along a line A-A′ in FIG. 21 in accordance with some embodiments of the present disclosure.

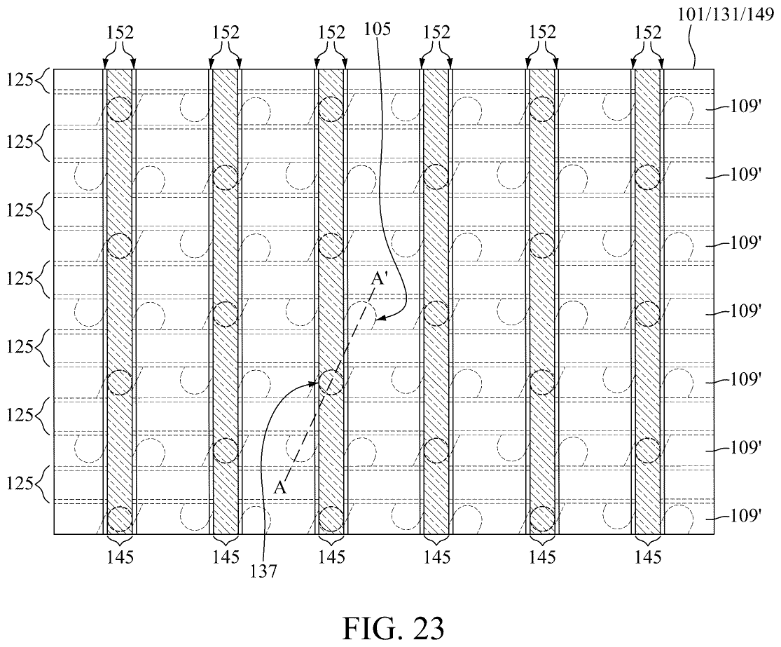

FIG. 23 is a top view of an intermediate stage of forming a dielectric layer surrounding the bit line structures and removing the dielectric spacers to form air gaps during the formation of the memory device in accordance with some embodiments of the present disclosure.

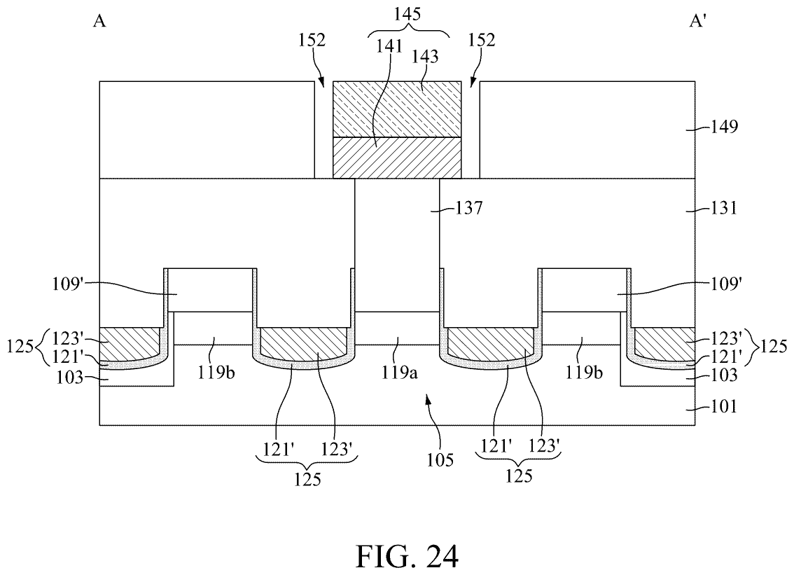

FIG. 24 is a cross-sectional view of an intermediate stage in the formation of the memory device along a line A-A′ in FIG. 23 in accordance with some embodiments of the present disclosure.

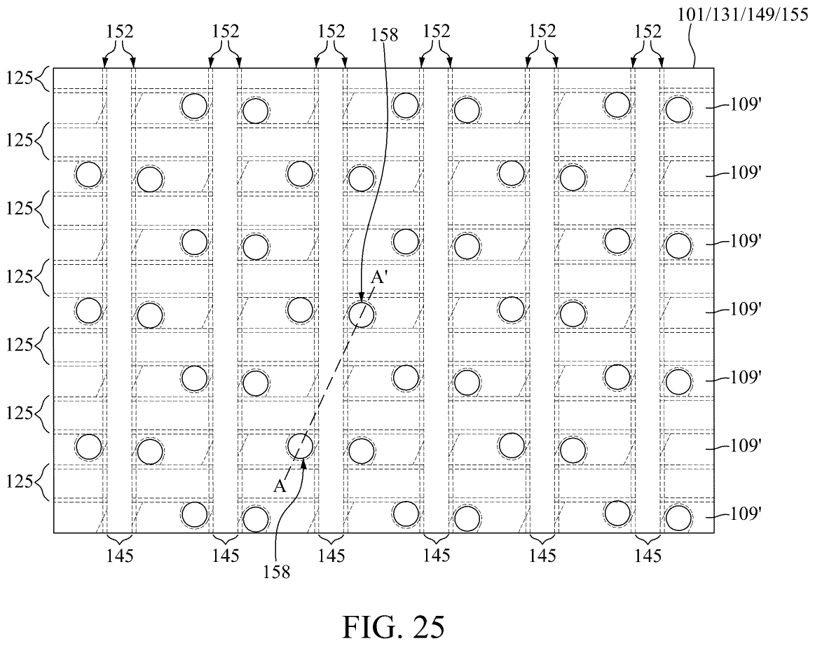

FIG. 25 is a top view of an intermediate stage of forming a dielectric layer covering the bit line structures and forming capacitor contact openings during the formation of the memory device in accordance with some embodiments of the present disclosure.

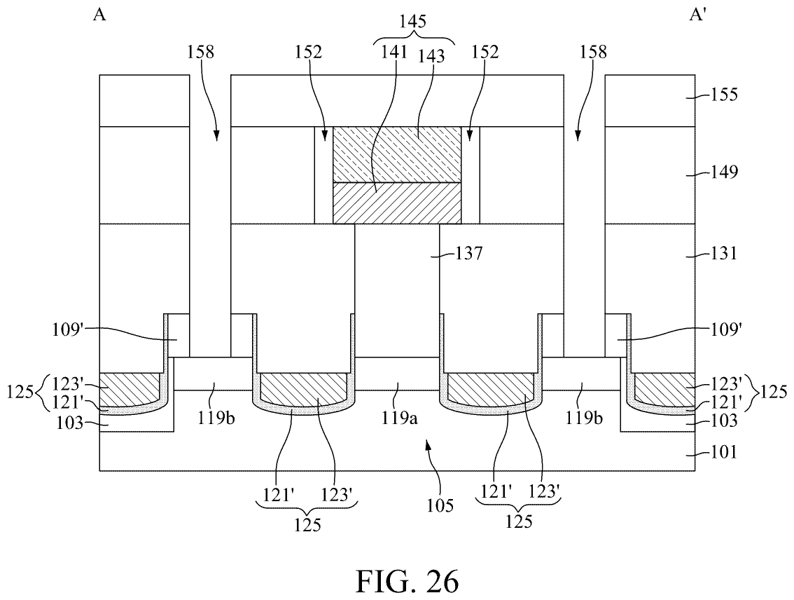

FIG. 26 is a cross-sectional view of an intermediate stage in the formation of the memory device along a line A-A′ in FIG. 25 in accordance with some embodiments of the present disclosure.

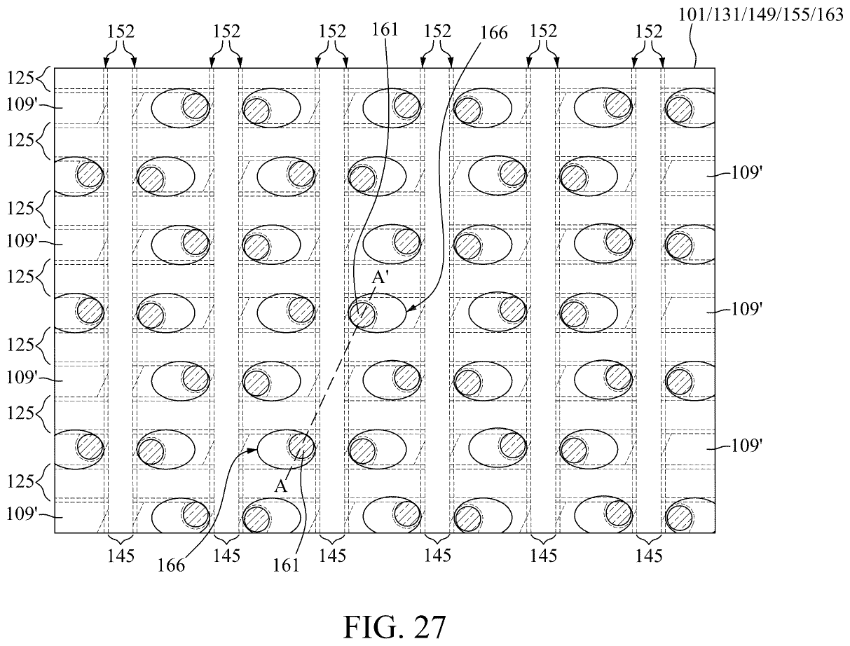

FIG. 27 is a top view of an intermediate stage of forming capacitor contacts, forming polysilicon stacks, forming a dielectric layer over the capacitor contacts, and forming capacitor openings in the dielectric layer during the formation of the memory device in accordance with some embodiments of the present disclosure.

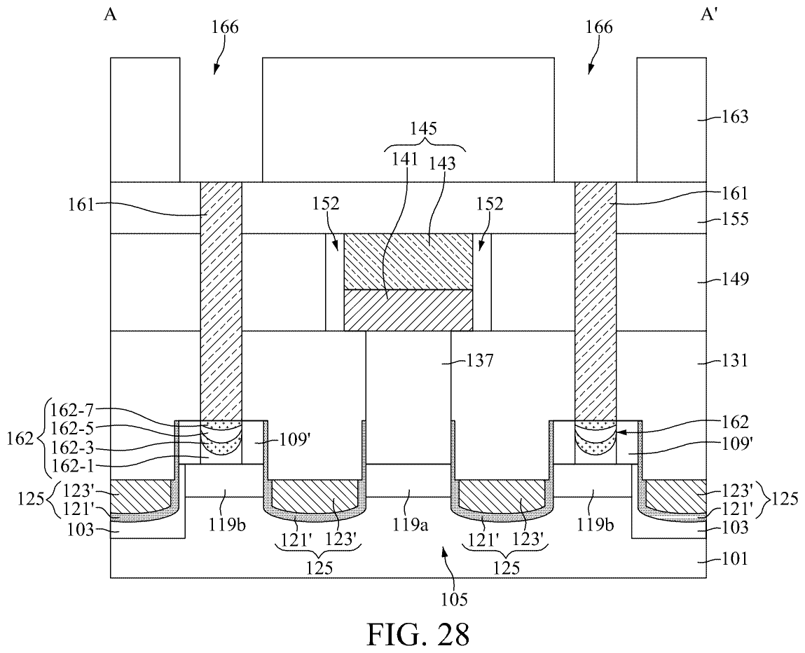

FIG. 28 is a cross-sectional view of an intermediate stage in the formation of the memory device along a line A-A′ in FIG. 27 in accordance with some embodiments of the present disclosure.

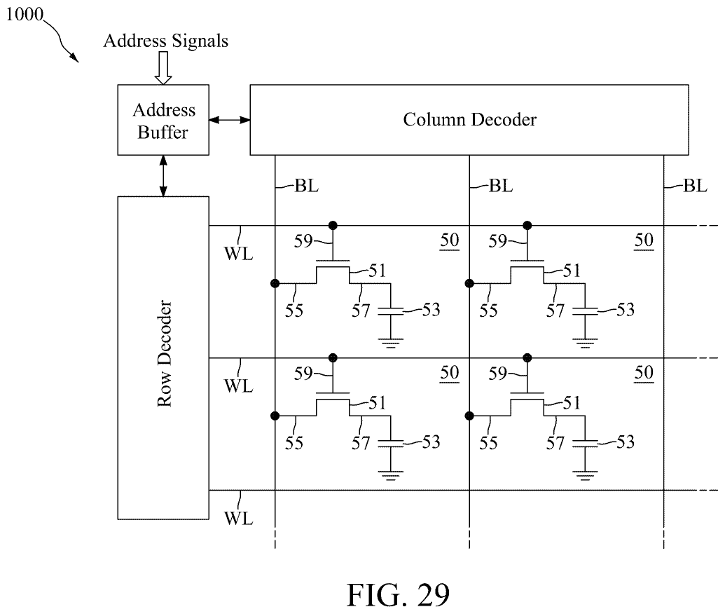

FIG. 29 is a partial schematic illustration of an exemplary integrated circuit, including an array of memory cells, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments of the present disclosure, FIG. 1 is a top view of a memory device 100, and FIG. 2 is a cross-sectional view of the memory device 100 along a line A-A′ in FIG. 1. FIG. 3 is an enlarged view of a portion P1 of the memory device 100 in FIG. 2, and FIG. 4 is an enlarged view of a portion P2 of the memory device 100 in FIG. 2.

As shown in FIGS. 1 and 2, the memory device 100 includes a semiconductor substrate 101, an isolation structure 103 disposed in the semiconductor substrate 101 defining a plurality of active areas 105, a plurality of word line structures 125 (i.e., gate structures) extending across the active areas 105, and a plurality of source/drain regions 119a and 119b in the active areas 105 separated by the word line structures 125. In some embodiments, each of the active areas 105 includes two source/drain regions 119b and one source/drain region 119a disposed between the source/drain regions 119b. In some embodiments, the source/drain regions 119a and 119b are formed of silicon phosphide, phosphorus-doped silicon carbon, silicon carbide, silicon germanium, silicon-germanium-tin alloy, or silicon-germanium-boron alloy. Moreover, each of the word line structures 125 includes a high-k gate dielectric layer 121′ and a metal gate electrode layer 123′ surrounded by the high-k gate dielectric layer 121′.

In some embodiments, the memory device 100 includes mask layers 109′ disposed over the source/drain regions 119b. In some embodiments, the memory device 100 includes a dielectric layer 131 covering the mask layers 109′ and the word line structures 125, and a dielectric layer 149 disposed over the dielectric layer 131. In some embodiments, the memory device 100 includes a plurality of bit line contacts 137 penetrating through the dielectric layer 131 to contact the source/drain regions 119a, and a plurality of bit line structures 145 penetrating through the dielectric layer 149 to contact the bit line contacts 137. In some embodiments, each of the bit line structures 145 includes a lower bit line layer 141 and an upper bit line layer 143 disposed over the lower bit line layer 141. In some embodiments, the bit line structures 145 are separated from the dielectric layer 149 by air gaps 152.

Additionally, the memory device 100 includes a dielectric layer 155 disposed over the dielectric layer 149, a plurality of capacitor contacts 161 penetrating through the dielectric layers 155, 149, 131 and extending to the mask layers 109′, a plurality of polysilicon stacks 162 disposed in the mask layers 109′ and between the capacitor contacts 161 and the source/drain regions 119b, and a dielectric layer 163 disposed over the dielectric layer 155. The memory device 100 further includes a plurality of capacitors 177 disposed in the dielectric layer 163 to contact the capacitor contacts 161, as shown in FIGS. 1 and 2.

Furthermore, the polysilicon stack 162 includes a first polysilicon layer 162-1, a second polysilicon layer 162-3 disposed over the first polysilicon layer 162-1, a third polysilicon layer 162-5 disposed over the second polysilicon layer 162-3, and a fourth polysilicon layer 162-7 disposed over the third polysilicon layer 162-5. In some embodiments, each of the first polysilicon layer 162-1, the second polysilicon layer 162-3, the third polysilicon layer 162-5 and the fourth polysilicon layer 162-7 is in direct contact with the mask layer 109′.

The first polysilicon layer 162-1 and the third polysilicon layer 162-5 are undoped, and the second polysilicon layer 162-3 and the fourth polysilicon layer 162-7 are doped. In some embodiments, a dopant concentration of the second polysilicon layer 162-3 is greater than a dopant concentration of the fourth polysilicon layer 162-7. In some embodiments, the second polysilicon layer 162-3 and the fourth polysilicon layer 162-7 are doped with arsenic (As), boron (B), or phosphorous (P). In some embodiments, each of the first polysilicon layer 162-1, the second polysilicon layer 162-3 and the third polysilicon layer 162-5 has a concave top surface facing the capacitor contact 161. In some embodiments, the first polysilicon layer 162-1, the second polysilicon layer 162-3 and the third polysilicon layer 162-5 have U-shaped or V-shaped profiles.

In some embodiments, each of the capacitors 177 includes a bottom electrode 171, a top electrode 175 disposed over and surrounded by the bottom electrode 171, and a dielectric layer 173 disposed between and in direct contact with the bottom electrode 171 and the top electrode 175. In some embodiments, the bit line structures 145 are electrically connected to the source/drain regions 119a through the bit line contacts 137, and the capacitors 177 are electrically connected to the source/drain regions 119b through the capacitor contacts 161 and the polysilicon stacks 162. In some embodiments, the memory device 100 is part of a DRAM.

As shown in FIG. 3, the high-k gate dielectric layer 121′ of the word line structure 125 has a first width W1 above a level of a top surface 123′T of the metal gate electrode layer 123′ of the word line structure 125, and a second width W2 below the level of the top surface 123′T of the metal gate electrode layer 123′ of the word line structure 125. In some embodiments, the second width W2 is greater than the first width W1. Moreover, in accordance with some embodiments, an interface INT1 between the dielectric layer 131 and the high-k gate dielectric layer 121′ of the word line structure 125 is substantially level with an interface INT2 between the dielectric layer 131 and the metal gate electrode layer 123′ of the word line structure 125.

As shown in FIG. 4, the high-k gate dielectric layer 121′ of the word line structure 125 has a third width W3 above the level of the top surface 123′T of the metal gate electrode layer 123′ of the word line structure 125, and a fourth width W4 below the level of the top surface 123′T of the metal gate electrode layer 123′ of the word line structure 125. In some embodiments, the fourth width W4 is greater than the third width W3. In some embodiments, the interface INT1 between the dielectric layer 131 and the high-k gate dielectric layer 121′ of the word line structure 125 is substantially level with the interface INT2 between the dielectric layer 131 and the metal gate electrode layer 123′ of the word line structure 125. In some embodiments, a top surface 121′T of the high-k gate dielectric layer 121′ of the word line structure 125 is substantially level with a top surface 109′T of the mask layer 109′.

Embodiments of the memory device 100 and the method for preparing the same are provided in the disclosure. In some embodiments, the memory device 100 includes the word line structures 125 disposed in the semiconductor substrate 101, wherein the word line structures 125 include the metal gate electrode layers 123′ and the high-k gate dielectric layers 121′ surrounding the metal gate electrode layers 123′. Therefore, gate-to-substrate leakage current is decreased while channel leakage current is suppressed and a channel length is increased, which are advantages of buried word line structures (i.e., the word line structures 125). Additionally, air gaps 152 may help to reduce parasitic capacitance, thereby improving device performance by minimizing signal noise. As a result, a performance of the memory device 100 is improved.

In accordance with some embodiments of the present disclosure, FIG. 5 is a flow diagram of a method 10 for preparing the memory device 100, wherein the method 10 includes steps S11, S13, S15, S17, S19, S21, S23, S25, S27, S29 and S31. The steps S11 to S31 of FIG. 5 are elaborated in connection with FIGS. 6 to 28.

FIGS. 6, 8, 10, 12, 15, 19, 21, 23, 25 and 27 are top views illustrating intermediate stages in the formation of the memory device 100, and FIGS. 7, 9, 11, 13, 14, 16, 18, 20, 22, 24, 26 and 28 are cross-sectional views illustrating intermediate stages in the formation of the memory device 100. It should be noted that FIGS. 7, 9, 11, 13, 16, 20, 22, 24, 26 and 28 are cross-sectional views along lines A-A′ in FIGS. 6, 8, 10, 12, 15, 19, 21, 23, 25 and 27, respectively. Moreover, FIG. 17 is an enlarged view of a portion P3 of the memory device 100 in FIG. 16.

As shown in FIGS. 6 and 7, a semiconductor substrate 101 is provided. The semiconductor substrate 101 may be a semiconductor wafer such as a silicon wafer. Alternatively, the semiconductor substrate 101 may include elementary semiconductor materials, compound semiconductor materials, and/or alloy semiconductor materials. Examples of the elementary semiconductor materials may include, but are not limited to, crystal silicon, polycrystalline silicon, amorphous silicon, germanium, and diamond. Examples of the compound semiconductor materials may include, but are not limited to, silicon carbide, gallium arsenic, gallium phosphide, indium phosphide, indium arsenide, and indium antimonide. Examples of the alloy semiconductor materials may include, but are not limited to, SiGe, GaAsP, AlInAs, AlGaAs, GaInAs, GaInP, and GaInAsP.

In some embodiments, the semiconductor substrate 101 includes an epitaxial layer. For example, the semiconductor substrate 101 has an epitaxial layer overlying a bulk semiconductor. In some embodiments, the semiconductor substrate 101 is a semiconductor-on-insulator substrate, which may include a substrate, a buried oxide layer over the substrate, and a semiconductor layer over the buried oxide layer, such as a silicon-on-insulator (SOI) substrate, a silicon germanium-on-insulator (SGOI) substrate, or a germanium-on-insulator (GOI) substrate. Semiconductor-on-insulator substrates can be fabricated using methods such as separation by implantation of oxygen (SIMOX), wafer bonding, and/or other suitable methods.

Still referring to FIGS. 6 and 7, in accordance with some embodiments, an isolation structure 103 is formed in the semiconductor substrate 101 to define a plurality of active areas 105, wherein the isolation structure 103 is a shallow trench isolation (STI) structure. In some embodiments, the isolation structure 103 may include silicon oxide, silicon nitride, silicon oxynitride or another suitable dielectric material, and formation of the isolation structure 103 may include forming a patterned mask over the semiconductor substrate 101; etching the semiconductor substrate 101 to form openings using the patterned mask as a mask; depositing a dielectric material in the openings and over the semiconductor substrate 101; and planarizing the dielectric material until a top surface of the semiconductor substrate 101 is exposed.

Moreover, a plurality of doped regions 107 are formed in the active areas 105 defined by the isolation structures 103. The respective step is illustrated as the step S11 in the method 10 shown in FIG. 5. In some embodiments, the doped regions 107 are formed using one or more ion implantation processes, and P-type dopants, such as boron (B), gallium (Ga), or indium (In), or N-type dopants, such as phosphorous (P) or arsenic (As), can be implanted in the active areas 105 to form the doped regions 107, depending on the conductivity type of the memory device 100. In some embodiments, the doped regions 107 will become source/drain regions of the memory device 100 in subsequent processes. In some embodiments, the doped regions 107 are formed of silicon phosphide, phosphorus-doped silicon carbon, silicon carbide, silicon germanium, silicon-germanium-tin alloy, or silicon-germanium-boron alloy.

After the formation of the doped regions 107, in accordance with some embodiments, a mask material 109 is formed over the semiconductor substrate 101, as shown in FIGS. 8 and 9. The respective step is illustrated as the step S13 in the method 10 shown in FIG. 5. In some embodiments, the isolation structures 103 and the doped regions 107 are covered by the mask material 109. Next, a patterned mask 111 with openings 114 is formed over the mask material 109. In some embodiments, the mask material 109 is partially exposed by the openings 114 of the patterned mask 111.

In some embodiments, the mask material 109 includes silicon nitride, silicon oxide, silicon oxynitride, another suitable material, or a combination thereof. In some embodiments, the mask material 109 and the patterned mask 111 consist of different materials, allowing for varying etching selectivity during a subsequent etching process. In some embodiments, the mask material 109 is formed using a deposition process, such as a chemical vapor deposition (CVD) process, a physical vapor deposition (PVD) process, an atomic layer deposition (ALD) process, a spin-coating process, or another suitable deposition process.

Next, the mask material 109 and the semiconductor substrate 101 are etched to form a plurality of trenches 116 using the patterned mask 111 as an etching mask, as shown in FIGS. 10 and 11. In some embodiments, the trenches 116 are parallel to each other. In some embodiments, the trenches 116 extend across the doped regions 107 in the active areas 105 to form the source/drain regions 119a and 119b, wherein the source/drain regions 119a are referred to as first source/drain regions and the source/drain regions 119b are referred to as second source/drain regions.

In some embodiments, the second source/drain regions 119b are located at opposite end portions of the active areas 105, and the first source/drain regions 119a are located at middle portions of the active areas 105. In some embodiments, remaining portions of the mask material 109 are referred to as mask layers 109′. In some embodiments, the trenches 116 are formed using a wet etching process, a dry etching process, or a combination thereof. The respective step is illustrated as the step S15 in the method 10 shown in FIG. 5.

After the formation of the trenches 116, the patterned mask 111 is removed, and a high-k dielectric material 121 is conformally deposited over the current structure, as shown in FIGS. 12 and 13. The respective step is illustrated as the step S17 in the method 10 shown in FIG. 5. In some embodiments, the patterned mask 111 is removed using a stripping process, an ashing process, an etching process, or another suitable method. After the removal of the patterned mask 111, top surfaces 109′T and sidewalls 109'S of the mask layers 109′ are exposed.

In some embodiments, the high-k dielectric material 121 is deposited to line the trenches 116. In some embodiments, the top surfaces 109′T and the sidewalls 109'S of the mask layers 109′ are covered by the high-k dielectric material 121. In some embodiments, the high-k dielectric material 121 includes HfSiON, HfON, another suitable dielectric material having a dielectric constant (k) higher than a dielectric constant of silicon dioxide, or a combination thereof. In some embodiments, the high-k dielectric material 121 is formed using a deposition process, such as a CVD process, a PVD process, an ALD process, a spin-coating process, or another suitable deposition process.

Subsequently, a metal material 123 is formed over the high-k dielectric material 121, as shown in FIG. 14. In some embodiments, remaining portions of the trenches 116 are filled with the metal material 123. In some embodiments, the metal material 123 extends over the top surfaces 109′T of the mask layers 109′. The respective step is illustrated as the step S19 in the method 10 shown in FIG. 5.

In some embodiments, the metal material 123 includes TiN, W, Ru, Al, a RuAl alloy, another suitable metal, or a combination thereof. In some embodiments, the metal material 123 is formed using a deposition process, such as a CVD process, a PVD process, a sputtering process, a plating process, or another suitable deposition process.

Next, the high-k dielectric material 121 and the metal material 123 are recessed to form a plurality of word line structures 125, as shown in FIGS. 15 and 16. The respective step is illustrated as the step S21 in the method 10 shown in FIG. 5. In some embodiments, the high-k dielectric material 121 and the metal material 123 are partially removed by an etching process. Remaining portions of the high-k dielectric material 121′ and remaining portions of the metal material 123′ collectively form the word line structures 125, wherein the remaining portions of the high-k dielectric material 121′ are referred to as high-k gate dielectric layers and the remaining portions of the metal material 123′ are referred to as metal gate electrode layers.

In some embodiments, after the etching process is performed, the top surfaces 109′T of the mask layers 109′ are exposed. In some embodiments, recesses 128 are formed over the word line structures 125. In some embodiments, the recess 128 has a fifth width W5 and the metal gate electrode layer 123′ of the word line structure 125 has a sixth width W6, wherein the fifth width W5 is greater than the sixth width W6.

FIG. 17 is an enlarged view of the portion P3 of the memory device 100 in FIG. 16 in accordance with some embodiments. As shown in FIG. 17, the high-k gate dielectric layer 121′ of the word line structure 125 has a first width W1 above a level of a top surface 123′T of the metal gate electrode layer 123′ of the word line structure 125, and a second width W2 below the level of the top surface 123′T of the metal gate electrode layer 123′ of the word line structure 125. In some embodiments, the second width W2 is greater than the first width W1.

Next, a dielectric layer 131 is formed to cover the mask layers 109′ and the word line structures 125, as shown in FIG. 18. The respective step is illustrated as the step S23 in the method 10 shown in FIG. 5. In some embodiments, the recesses 128 are filled with portions of the dielectric layer 131, such as the portion 131P of the dielectric layer 131. In such embodiments, a dotted line indicating a boundary of the portion 131P in FIG. 18 is used to clarify the disclosure. No obvious interface exists in the dielectric layer 131.

Each of the high-k gate dielectric layers 121′ has a portion 121′P sandwiched between the adjacent mask layer 109′ and the portion 131P of the dielectric layer 131 deposited in the recess 128. In some embodiments, the portion 131P of the dielectric layer 131 has the fifth width W5 and the metal gate electrode layer 123′ of the word line structure 125 has the sixth width W6, wherein the fifth width W5 is greater than the sixth width W6. Additionally, in some embodiments, the dielectric layer 131 includes silicon oxide, silicon nitride, silicon oxynitride, another suitable dielectric material, or a combination thereof. Furthermore, the dielectric layer 131 may be formed using a deposition process, such as a CVD process, a PVD process, an ALD process, a spin-coating process, or another suitable deposition process.

Subsequently, a plurality of bit line contact openings 134 are formed to expose the first source/drain regions 119a, as shown in FIGS. 19 and 20. The formation of the openings 134 may include forming a patterned mask over the dielectric layer 131, and etching the dielectric layer 131 using the patterned mask as a mask. The etching process may be a wet etching process, a dry etching process, or a combination thereof. After the formation of the bit line contact openings 134, the patterned mask may be removed.

Next, a plurality of bit line contacts 137 are formed in the bit line contact openings 134, and a plurality of bit line structures 145 are formed over the bit line contacts 137, as shown in FIGS. 21 and 22. The respective steps are illustrated as the steps S25 and S27 in the method 10 shown in FIG. 5. In some embodiments, each of the bit line structures 145 includes a lower bit line layer 141 and an upper bit line layer 143 disposed over the lower bit line layer 141. In some embodiments, the bit line structures 145 are electrically connected to the first source/drain regions 119a.

In some embodiments, the bit line contacts 137 include polysilicon, W, Al, Cu, Ni, Co, another suitable conductive material, or a combination thereof. The formation of the bit line contacts 137 may include depositing a bit line contact material in the bit line contact openings 134 and over the dielectric layer 131, and performing a planarization process to remove excess portions of the bit line contact material over the bit line contact openings 134. The deposition process may include a CVD process, a PVD process, an ALD process, a spin-coating process, or another suitable deposition process. The planarization process may include a chemical mechanical polishing (CMP) process.

Moreover, the formation of the bit line structures 145 may include forming a lower bit line material over the dielectric layer 131, forming an upper bit line material over the lower bit line material, forming a patterned mask over the upper bit line material, and etching the upper bit line material and the lower bit line material using the patterned mask as a mask. In some embodiments, remaining portions of the lower bit line material are referred to as the lower bit line layers 141, and remaining portions of the upper bit line material are referred to as the upper bit line layers 143. After the formation of the bit line structures 145, the patterned mask may be removed. In some embodiments, the lower bit line layers 141 include TiN, TaN, TaC, TiC, another suitable conductive material, or a combination thereof. In some embodiments, the upper bit line layers 143 include W, Ti, Ni, Co, another suitable conductive material, or a combination thereof.

Next, a plurality of dielectric spacers 147 are formed on sidewalls of the bit line structures 145, as shown in FIGS. 21 and 22. In some embodiments, the dielectric spacers 147 include a doped spin-on-glass (SOG) material, such as phosphosilicate glass (PSG) or borophosphosilicate glass (BPSG). In some embodiments, the dielectric spacers 147 are formed using a deposition process and a subsequent planarization process. The deposition process may include a CVD process, a PVD process, an ALD process, a spin-coating process, or another suitable deposition process. The planarization process may include a CMP process. The planarization process may be performed to expose top surfaces of the bit line structures 145.

Subsequently, a dielectric layer 149 is formed to surround the dielectric spacers 147 and the bit line structures 145, and the dielectric spacers 147 are removed to form air gaps 152 between the bit line structures 145 and the dielectric layer 149, as shown in FIGS. 23 and 24. In some embodiments, the air gaps 152 are formed on the sidewalls of the bit line structures 145, and the bit line structures 145 are separated from the dielectric layer 149 by the air gaps 152.

In some embodiments, the dielectric layer 149 includes silicon oxide, silicon nitride, silicon oxynitride, another suitable dielectric material, or a combination thereof. Moreover, the dielectric layer 149 is formed using a deposition process and a subsequent planarization process. The deposition process may include a CVD process, a PVD process, an ALD process, a spin-coating process, or another suitable deposition process. The planarization process may include a CMP process. After the planarization process and prior to the removal of the dielectric spacers 147, a top surface of the dielectric layer 149 is coplanar with the top surfaces of the bit line structures 145 and top surfaces of the dielectric spacers 147.

In some embodiments, after the formation of the dielectric layer 149, the dielectric spacers 147 are removed using a vapor phase hydrofluoric acid (VHF) etching process. During the VHF etching process, the dielectric spacers 147 have a high selectivity to the dielectric layer 149. Therefore, the dielectric spacers 147 are removed by the etching process, while the dielectric layer 149 may be substantially left in place, thereby forming the air gaps 152.

Next, a dielectric layer 155 is formed over the dielectric layer 149 to seal the air gaps 152, and a plurality of capacitor contact openings 158 are formed to expose the second source/drain regions 119b, as shown in FIGS. 25 and 26. Materials and processes used for the formation of the dielectric layer 155 are similar to or same as materials and processes used for the formation of the dielectric layer 149, and details thereof are not repeated. In some embodiments, the dielectric layer 155 is formed using a spin-coating process, sealing the air gaps 152 with high aspect ratios while allowing the air gaps 152 to remain unfilled by the dielectric layer 155.

In some embodiments, the capacitor contact openings 158 are formed to penetrate through the dielectric layers 155, 149 and 131 and the mask layers 109′. The formation of the capacitor contact openings 158 may include forming a patterned mask over the dielectric layer 155, and etching the dielectric layers 155, 149 and 131 and the mask layers 109′ using the patterned mask as a mask. The etching process may be a wet etching process, a dry etching process, or a combination thereof. After the formation of the capacitor contact openings 158, the patterned mask may be removed.

Next, a plurality of polysilicon stacks 162 and a plurality of capacitor contacts 161 are formed in the capacitor contact openings 158, as shown in FIGS. 27 and 28. The respective step is illustrated as the step S29 in the method 10 shown in FIG. 5.

The polysilicon stack 162 is disposed over and in contact with the second source/drain region 119b. In accordance with some embodiments, the polysilicon stack 162 includes a first polysilicon layer 162-1, a second polysilicon layer 162-3 disposed over the first polysilicon layer 162-1, a third polysilicon layer 162-5 disposed over the second polysilicon layer 162-3, and a fourth polysilicon layer 162-7 disposed over the third polysilicon layer 162-5. In some embodiments, each of the first polysilicon layer 162-1, the second polysilicon layer 162-3, the third polysilicon layer 162-5 and the fourth polysilicon layer 162-7 is in direct contact with the mask layer 109′.

Additionally, the first polysilicon layer 162-1 and the third polysilicon layer 162-5 are undoped, and the second polysilicon layer 162-3 and the fourth polysilicon layer 162-7 are doped. In some embodiments, a dopant concentration of the second polysilicon layer 162-3 is greater than a dopant concentration of the fourth polysilicon layer 162-7. In some embodiments, the second polysilicon layer 162-3 and the fourth polysilicon layer 162-7 are doped with arsenic (As), boron (B), or phosphorous (P). In some embodiments, each of the first polysilicon layer 162-1, the second polysilicon layer 162-3 and the third polysilicon layer 162-5 has a concave top surface facing the capacitor contact 161. In some embodiments, the first polysilicon layer 162-1, the second polysilicon layer 162-3 and the third polysilicon layer 162-5 have U-shaped or V-shaped profiles.

In some embodiments, the first polysilicon layer 162-1 is formed using a deposition process, such as a CVD process, a PVD process, an ALD process, or a combination thereof. After the deposition process, an etch-back process may be performed to remove excess portion(s) of the first polysilicon layer 162-1 in an upper portion of the capacitor contact opening 158 and/or over a top surface of the dielectric layer 155.

Subsequently, the second polysilicon layer 162-3 is formed in the capacitor contact opening 158 and over the first polysilicon layer 162-1. In some embodiments, the second polysilicon layer 162-3 is formed using a deposition process, such as a CVD process, a PVD process, an ALD process, or a combination thereof. In some embodiments, the second polysilicon layer 162-3 is doped with arsenic (As), boron (B), or phosphorous (P), and the second polysilicon layer 162-3 is in-situ doped during the deposition process. In some embodiments, the second polysilicon layer 162-3 is not in-situ doped, and instead an implantation process is performed to dope the second polysilicon layer 162-3. After the deposition process, an etch-back process may be performed to remove excess portion(s) of the second polysilicon layer 162-3 in the upper portion of the capacitor contact opening 158 and/or over the top surface of the dielectric layer 155.

Next, the third polysilicon layer 162-5 is formed in the capacitor contact openings 158 and over the second polysilicon layer 162-3. In some embodiments, the third polysilicon layer 162-5 is undoped, and is formed using a deposition process, such as a CVD process, a PVD process, an ALD process, or a combination thereof. After the deposition process, an etch-back process may be performed to remove excess portion(s) of the third polysilicon layer 162-5 in the upper portion of the capacitor contact opening 158 and/or over the top surface of the dielectric layer 155.

Next, the fourth polysilicon layer 162-7 is formed in the capacitor contact opening 158 and over the third polysilicon layer 162-5. In some embodiments, the fourth polysilicon layer 162-7 is formed using a deposition process, such as a CVD process, a PVD process, an ALD process, or a combination thereof. In some embodiments, the fourth polysilicon layer 162-7 is doped with arsenic (As), boron (B), or phosphorous (P), and a dopant concentration of the second polysilicon layer 162-3 is greater than a dopant concentration of the fourth polysilicon layer 162-7.

In some embodiments, the fourth polysilicon layer 162-7 is in-situ doped during the deposition process. In some embodiments, the fourth polysilicon layer 162-7 is not in-situ doped, and instead an implantation process is performed to dope the fourth polysilicon layer 162-7. After the deposition process, an etch-back process may be performed to remove excess portion(s) of the fourth polysilicon layer 147 in the upper portion of the capacitor contact opening 158 and/or over the top surface of the dielectric layer 155.

After the etch-back process is performed, remaining portions of the fourth polysilicon layer 162-7, the third polysilicon layer 162-5, the second polysilicon layer 162-3 and the first polysilicon layer 162-1 collectively form a polysilicon stack 162, which occupies a lower portion of the capacitor contact openings 158. In some embodiments, the polysilicon stack 162 has a substantially flat top surface.

It should be noted that the polysilicon stack 162 may have more than four polysilicon layers. In some embodiments, processes for forming the third polysilicon layer 162-5 and the fourth polysilicon layer 162-7 are repeated as a cycle to form more polysilicon layers over the fourth polysilicon layer 162-7. For example, a fifth polysilicon layer, which is undoped, is formed over the fourth polysilicon layer 162-7, and a sixth polysilicon layer, which is doped with arsenic (As), boron (B), or phosphorous (P), is formed over the fifth polysilicon layer. In such embodiments, a dopant concentration of the fourth polysilicon layer 162-7 is greater than a dopant concentration of the sixth polysilicon layer, and the topmost polysilicon layer has a substantially flat top surface.

The capacitor contacts 161 are disposed over the polysilicon stacks 162 and electrically connect the second source/drain regions 119b to the subsequently-formed capacitors 177. In accordance with some embodiments, the capacitor contacts 161 are made of a conductive material, such as Cu, W, Al, Ti, Ta, Au, Ag, another suitable conductive material, or a combination thereof. The capacitor contacts 161 may be formed using a deposition process and a subsequent planarization process. The deposition process may include a CVD process, a PVD process, a sputtering process, a plating process, or another suitable process. The planarization process may be a CMP process.

Still referring to FIGS. 27 and 28, a dielectric layer 163 is formed over the dielectric layer 155 to cover the capacitor contacts 161. Materials and processes used for the formation of the dielectric layer 163 are similar to or same as materials and processes used for the formation of the dielectric layer 155, and details thereof are not repeated.

In accordance with some embodiments, a plurality of capacitor openings 166 are formed to penetrate through the dielectric layer 163 and expose the capacitor contacts 161. The formation of the capacitor openings 166 may include forming a patterned mask over the dielectric layer 163, and etching the dielectric layer 163 using the patterned mask as a mask to expose the capacitor contacts 161. The etching process may be a wet etching process, a dry etching process, or a combination thereof. After the formation of the capacitor openings 166, the patterned mask may be removed.

Subsequently, referring back to FIGS. 1 and 2, in accordance with some embodiments, a plurality of capacitors 177 are formed in the capacitor openings 166 in the dielectric layer 163. In accordance with some embodiments, each of the capacitors 177 includes a bottom electrode 171, a top electrode 175, and a dielectric layer 173 sandwiched between the bottom electrode 171 and the top electrode 175. The respective step is illustrated as the step S31 in the method 10 shown in FIG. 5.

In some embodiments, the top electrodes 175, the dielectric layers 173, and the bottom electrodes 171 collectively form the capacitors 177, and the capacitors 177 are electrically connected to the second source/drain regions 119b. The formation of the capacitors 177 may include sequentially depositing a conductive material, a dielectric material and another conductive material in the capacitor openings 166 (see FIGS. 27 and 28) and over the dielectric layer 163, and performing a planarization process (e.g., a CMP process) to remove excess portions of the two conductive materials and the dielectric material.

In some embodiments, the bottom electrodes 171 include TiN or another suitable conductive material. In some embodiments, the dielectric layers 173 include a dielectric material, such as SiO₂, HfO₂, Al₂O₃, ZrO₂, another suitable dielectric material, or a combination thereof. In some embodiments, the top electrodes 175 include TiN, low-stress SiGe, another suitable conductive material, or a combination thereof. After the formation of the capacitors 177, the memory device 100 is obtained. In some embodiments, the memory device 100 is part of a DRAM.

FIG. 29 is a partial schematic illustration of an exemplary integrated circuit, such as a memory device 1000, including an array of memory cells 50, in accordance with some embodiments. In some embodiments, the memory device 1000 includes a DRAM. In some embodiments, the memory device 1000 includes a number of memory cells 50 arranged in a grid pattern and including a number of rows and columns. The number of memory cells 50 may vary depending on system requirements and fabrication technology.

In some embodiments, each of the memory cells 50 includes an access device and a storage device. The access device is configured to provide controlled access to the storage device. In particular, in accordance with some embodiments, the access device is a field-effect transistor (FET) 51 and the storage device is a capacitor 53. In each of the memory cells 50, the FET 51 includes a drain 55, a source 57 and a gate 59. One terminal of the capacitor 53 is electrically connected to the source 57 of the FET 51, and the other terminal of the capacitor 53 may be electrically connected to ground. In addition, in each of the memory cells 50, the gate 59 of the FET 51 is electrically connected to a word line WL, and the drain 55 of the FET 51 is electrically connected to a bit line BL.

The above description describes the source 57 of the FET 51 being electrically connected to the capacitor 53, and the drain 55 of the FET 51 being electrically connected to the bit line BL. However, during read and write operations, the drain of the FET 51 may be electrically connected to the capacitor 53, and the source of the FET 51 may be electrically connected to the bit line BL. In other words, either terminal of the FET 51 could be a source or a drain depending on a manner in which the FET 51 is controlled by voltages applied to the source, the drain and the gate.

By controlling the voltage at the gate 59 via the word line WL, a voltage potential may be created across the FET 51 such that an electrical charge can flow from the drain 55 to the capacitor 53. Therefore, an electrical charge stored in the capacitor 53 may be interpreted as a binary data value in the memory cell 50. For example, a positive charge above a threshold voltage stored in the capacitor 53 may be interpreted as binary “1.” If the charge in the capacitor 53 is below the threshold value, a binary value of “0” is said to be stored in the memory cell 50.

The bit lines BL are configured to read and write data to and from the memory cells 50. The word lines WL are configured to activate the FET 51 to access a particular row of the memory cells 50. Accordingly, the memory device 1000 also includes a periphery circuit region, which may include an address buffer, a row decoder and a column decoder. The row decoder and the column decoder selectively access the memory cells 50 in response to address signals that are provided to the address buffer during read, write and refresh operations. The address signals are typically provided by an external controller such as a microprocessor or another type of memory controller.

Referring back to FIGS. 1 and 2, the memory device 100 is located in an array region. The array region may be any of the regions of the memory cells 50 in the memory device 1000.

Embodiments of the memory device 100 and a method for preparing the same are provided in the disclosure. In some embodiments, the memory device 100 includes the word line structures 125 disposed in the semiconductor substrate 101, wherein the word line structures 125 include the metal gate electrode layers 123′ and the high-k gate dielectric layers 121′ surrounding the metal gate electrode layers 123′. Therefore, gate-to-substrate leakage current can be reduced while suppressing channel leakage current and enlarging a channel length, which are advantages of buried word line structures (i.e., the word line structures 125). In addition, the air gaps 152 may help to reduce parasitic capacitance and correspondingly improve device performance (e.g., by reducing signal noise). As a result, a performance of the memory device 100 is enhanced.

One aspect of the present disclosure provides a memory device including a semiconductor substrate having an active area; a word line structure extending across the active area, wherein the word line structure comprises a metal gate electrode layer and a high-k gate dielectric layer surrounding the metal gate electrode layer; a first source/drain region and a second source/drain region disposed in the active area and at opposite sides of the word line structure; a bit line structure disposed over and electrically connected to the first source/drain region; and a capacitor disposed over and electrically connected to the second source/drain region. The first source/drain region and the second source/drain region are formed of silicon phosphide, phosphorus-doped silicon carbon, silicon carbide, silicon germanium, silicon-germanium-tin alloy, or silicon-germanium-boron alloy.

Another aspect of the present disclosure provides a memory device including a semiconductor substrate having an active area; a word line structure extending across the active area, wherein the word line structure comprises a metal gate electrode layer and a high-k gate dielectric layer surrounding the metal gate electrode layer; a first source/drain region and a second source/drain region disposed in the active area and at opposite sides of the word line structure; a dielectric layer disposed over the semiconductor substrate and covering the word line structure, wherein an interface between the dielectric layer and the high-k gate dielectric layer is substantially level with an interface between the dielectric layer and the metal gate electrode layer; a bit line structure disposed over the dielectric layer and electrically connected to the first source/drain region; a capacitor disposed over the dielectric layer and electrically connected to the second source/drain region; a mask layer disposed between the second source/drain region and the capacitor, wherein the mask layer is in direct contact with the high-k gate dielectric layer; and a polysilicon stack disposed in the mask layer. The polysilicon stack comprises a first polysilicon layer and a second polysilicon layer disposed over the first polysilicon layer, wherein the first polysilicon layer is undoped and the second polysilicon layer is doped.

Another aspect of the present disclosure provides a method for preparing a memory device. The method includes forming a doped region in a semiconductor substrate; performing a first etching process on the semiconductor substrate to form a trench, thereby forming a first source/drain region and a second source/drain region in the doped region and at opposite sides of the trench; forming a high-k dielectric material lining the trench, and filling the trench with a metal material; performing a second etching process on the high-k dielectric material and the metal material to form a recess, thereby forming a high-k gate dielectric layer of a word line structure and a metal gate electrode layer of the word line structure, wherein a width of the recess is greater than a width of the metal gate electrode layer; forming a bit line structure over and electrically connected to the first source/drain region; and forming a capacitor over and electrically connected to the second source/drain region.

Another aspect of the present disclosure provides a method for preparing a memory device. The method includes forming a doped region in a semiconductor substrate; depositing a mask material over the substrate; forming a patterned mask with an opening over the mask material; performing a first etching process on the substrate using the patterned mask as an etching mask to form a trench in the substrate, and forming a mask layer, a first source/drain region and a second source/drain region, wherein the first source/drain region and the second source/drain region are at opposite sides of the trench, and wherein the mask layer is over the first source/drain region and the second source/drain region; forming a high-k dielectric material lining the trench, and filling the trench with a metal material; performing a second etching process on the high-k dielectric material and the metal material to form a recess, thereby forming a high-k gate dielectric layer of a word line structure and a metal gate electrode layer of the word line structure, wherein a width of the recess is greater than a width of the metal gate electrode layer; depositing a dielectric layer covering the mask layer and the word line structures; forming a bit line structure over and electrically connected to the first source/drain region; and forming a capacitor over and electrically connected to the second source/drain region.

The embodiments of the present disclosure have some advantageous features. By forming word line structures with high-k gate dielectric layers in array regions, gate-to-substrate leakage current can be reduced while suppressing channel leakage current and enlarging channel length. As a result, a performance of a memory device is enhanced.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A memory device, comprising:
a semiconductor substrate having an active area;
a word line structure extending across the active area, wherein the word line structure comprises a metal gate electrode layer and a high-k gate dielectric layer surrounding the metal gate electrode layer;
a first source/drain region and a second source/drain region disposed in the active area and at opposite sides of the word line structure;
a bit line structure disposed over and electrically connected to the first source/drain region; and
a capacitor disposed over and electrically connected to the second source/drain region,
wherein the first source/drain region and the second source/drain region are formed of silicon phosphide, phosphorus-doped silicon carbon, silicon carbide, silicon germanium, silicon-germanium-tin alloy, or silicon-germanium-boron alloy.

2. The memory device of claim 1, wherein the high-k gate dielectric layer has a first width above a level of a top surface of the metal gate electrode and a second width below the level of the top surface of the metal gate electrode, and wherein the second width is greater than the first width.

3. The memory device of claim 1, further comprising:
a bit line contact disposed between the first source/drain region and the bit line structure, wherein the bit line contact is in direct contact with the high-k gate dielectric layer.

4. The memory device of claim 3, further comprising:
a dielectric layer covering the word line structure, wherein a portion of the high-k gate dielectric layer is sandwiched between the dielectric layer and the bit line contact.

5. The memory device of claim 4, wherein the dielectric layer has a portion surrounded by the high-k gate dielectric layer, wherein a width of the portion of the dielectric layer is greater than a width of the metal gate electrode layer.

6. The memory device of claim 1, further comprising:
a mask layer disposed between the second source/drain region and the capacitor, wherein the mask layer is in direct contact with the high-k gate dielectric layer.

7. The memory device of claim 6, wherein the high-k gate dielectric layer has a third width adjacent to the mask layer and a fourth width adjacent to the second source/drain region, wherein the fourth width is greater than the third width.

8. The memory device of claim 6, wherein a top surface of the high-k gate dielectric layer is substantially level with a top surface of the mask layer.
